(19) United States
(12) Patent Application Publication
(10) Pub. No.: US 2024/0421194 A1
(43) Pub. Date: Dec. 19, 2024

(54) GALLIUM NITRIDE DEVICE WITH ARTIFICIAL FIELD PLATES

(71) Applicant: Taiwan Semiconductor Manufacturing Co., Ltd., Hsinchu (TW)

(72) Inventors: Yi-An LAI, Taipei City (TW); Pan Chieh Yu, Hsinchu (TW); Chih-Hua WANG, Hsinchu City (TW); Chan-Hong CHERN, Palo Alto, CA (US); Cheng-Hsiang HSIEH, Taipei City (TW)

(73) Assignee: Taiwan Semiconductor Manufacturing Co., Ltd., Hsinchu (TW)

(21) Appl. No.: 18/336,382

(22) Filed: Jun. 16, 2023

(51) Int. Cl. H01L 29/20; H01L 29/40; H01L 29/66; H01L 29/778

(52) U.S. Cl. CPC H01L 29/2003; H01L 29/401; H01L 29/402; H01L 29/66462; H01L 29/7786

(57) ABSTRACT

The present disclosure describes a semiconductor device having artificial field plates. The semiconductor device includes a first gallium nitride (GaN) layer on a substrate, an aluminum gallium nitride (AlGaN) layer on the first GaN layer, and a second GaN layer on the AlGaN layer. The first and second GaN layers includes different types of dopants. The semiconductor device further includes a gate contact structure in contact with the second GaN layer, first and second source/drain (S/D) contact structures in contact with the AlGaN layer, one or more artificial field plates between the gate contact structure and the first S/D contact structure. The first and second S/D contact structures are disposed at opposite sides of the gate contact structure. The one or more artificial field plates are separated from the first and second S/D contact structures and above the AlGaN layer.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs), and gallium nitride (GaN) high electron mobility transistors (HEMTs). Such scaling down has increased the complexity of semiconductor manufacturing processes and increased the difficulty of defects control in the semiconductor devices.

### BRIEF DESCRIPTION OF THE DRAWINGS

Aspects of the present disclosure are best understood from the following detailed description when read with the accompanying figures.

FIG. 1 illustrates a plan view of a gallium nitride (GaN) device having artificial field plates, in accordance with some embodiments.

FIG. 2 illustrates a cross-sectional view of a GaN device having artificial field plates, in accordance with some embodiments.

FIG. 3 illustrates a schematic diagram showing a GaN device in the context of a circuit, in accordance with some embodiments of the present disclosure.

FIG. 4 is a flow diagram of a method for fabricating a GaN device having artificial field plates, in accordance with some embodiments of the present disclosure.

FIGS. 5-18 illustrate plan views and cross-sectional views of a GaN device having artificial field plates at various stages of its fabrication process, in accordance with some embodiments of the present disclosure.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

Compared to silicon-based power devices, gallium nitride (GaN) high electron mobility transistor (HEMT) power devices can have lower on-resistance, higher operation frequency, and ultra-high breakdown voltage, and thus can achieve better performance. Additionally, GaN-on-silicon lateral HEMT power devices can have higher integration, lower cost, and easier mass production than vertical GaN HEMT power devices. However, GaN-on-silicon lateral HEMT power devices can have their challenges, such as high device failure rate (e.g., about 600 to about 800 parts per million (ppm)), compared to the device failure rate requirement of about 1 to about 5 ppm for automotive grade GaN power devices.

In the lateral GaN power devices, GaN layers can grow on a silicon (Si) substrate. As GaN and Si have different lattice constants, epitaxial growth defects and mismatch defects can form in the GaN layers. Additionally, back-end processes can also introduce metal particles and etching defects. These defects can lead to device failure after hundreds of hours in a high temperature reliability test, and thus can decrease lateral GaN power device performance and increase the device failure rate. Various tests, such as inline wafer acceptance test (WAT), chip probing (CP), and final test (FT), can be implemented to monitor the defects in GaN power devices. The dimension of the defects can range from about 1 μm² to about 6 μm². As a result, these defects may not be detected during these tests. In-line scan tools and microscopes may monitor these defects on inter-metal dielectric layers, field plates, and the drift region of lateral GaN power devices. However, manufacturing time and cost can increase with in-line scans and microscope images on every GaN power device.

Various embodiments in the present disclosure provide example methods for forming one or more artificial field plates in a lateral GaN HEMT device and/or other semiconductor device in an integrated circuit (IC). The GaN device can include a first GaN layer on a substrate, an aluminum gallium nitride (AlGaN) layer on the first GaN layer, and a second GaN layer on the AlGaN layer. First and second source/drain (S/D) contact structures of the GaN device can be in contact with the AlGaN layer. A gate contact structure of the GaN device can be in contact with the second GaN layer. The one or more artificial field plates can be located between the gate and the first S/D contact structures, and can be separated from the first and second S/D structures. In some embodiments, the one or more artificial field plates can increase defect detection sensitivity during tests and can help evaluate device performance impact of defects in the inter metal dielectric layers and the drift region. In some embodiments, the one or more artificial field plates can improve electric-field uniformity between the gate and first S/D contact structures and improve device performance. In some embodiments, the one or more artificial field plates can reduce GaN device manufacturing cost and improve defect control.

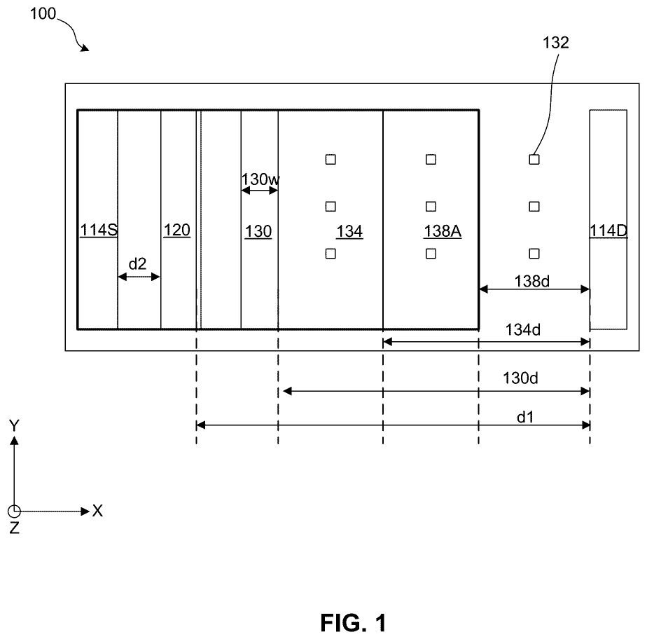

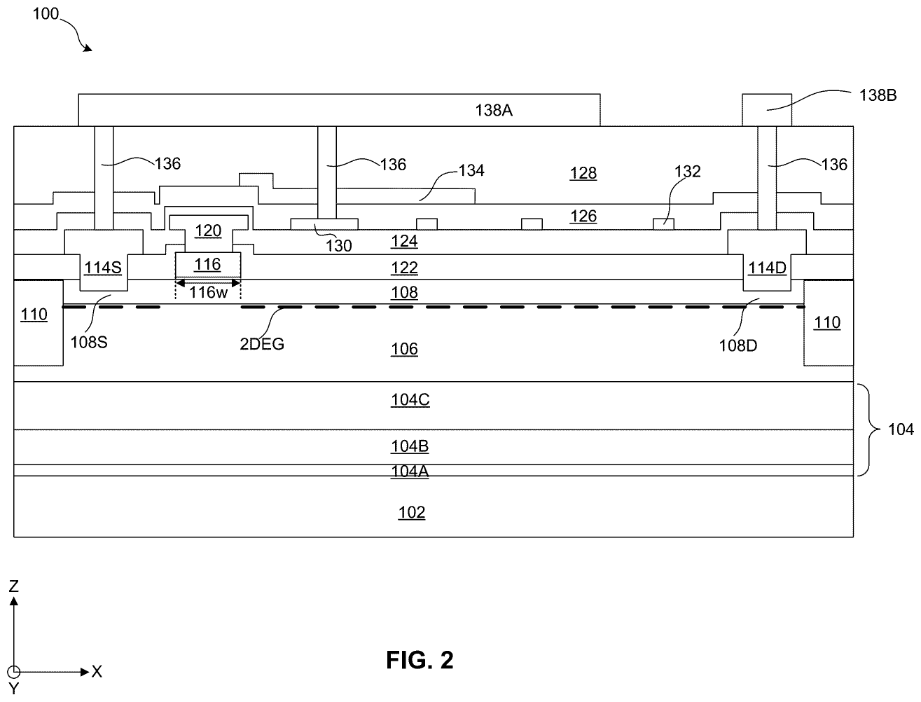

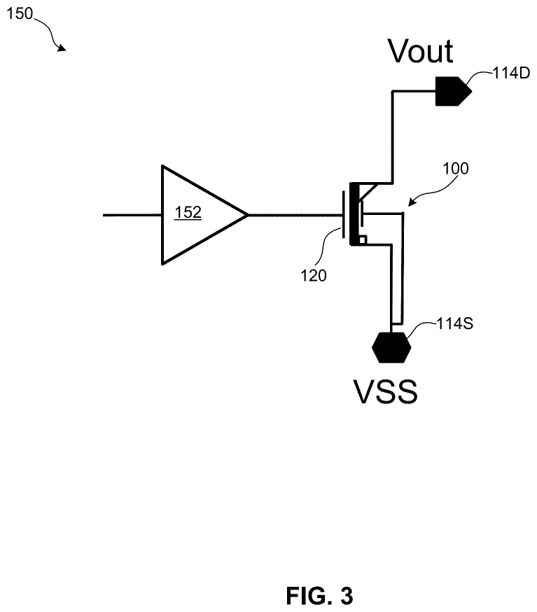

FIG. 1 illustrates a plan view of a GaN device 100 having one or more artificial field plates, in accordance with some embodiments. FIG. 2 illustrates a cross-sectional view of GaN device 100 having one or more artificial field plates, in accordance with some embodiments. FIG. 3 illustrates a schematic diagram of a GaN device 100 in the context of a circuit 150, in accordance with some embodiments of the present disclosure. Though FIGS. 1-3 illustrate a single GaN HEMT transistor, GaN device 100 can have any number of GaN HEMT transistors. In addition, GaN device 100 can be incorporated into an IC through the use of other structural components, such as conductive vias, conductive lines, dielectric layers, and interconnects, which are not shown for simplicity. The discussion of elements of GaN device 100 with the same annotations applies to each figure, unless mentioned otherwise. And like reference numerals generally indicate identical, functionally similar, and/or structurally similar elements.

Referring in FIGS. 1-3, GaN device 100 can include a substrate 102, a transition layer 104, a first GaN layer 106, an AlGaN layer 108, isolation regions 110, first and second S/D contact structures 114D and 114S, a second GaN layer 116, and a gate contact structure 120. In some embodiments, GaN device 100 can further include passivation layer 122, nitride layer 124, oxide layer 126, inter-layer dielectric (ILD) layer 128, first, second, and third field plates 130, 134, and 138A, artificial field plates 132, metal vias 136, and metal lines 138B.

Referring to FIG. 2, GaN device 100 can be fabricated on substrate 102. As used herein, the term “substrate” describes a material onto which subsequent material layers are added. Substrate 102 may be patterned. Materials added on substrate 102 may be patterned or may remain unpatterned. Substrate 102 can be a bulk semiconductor wafer or the top semiconductor layer of a semiconductor-on-insulator (SOI) wafer (not shown). In some embodiments, substrate 102 can include a crystalline semiconductor layer with its top surface parallel to the (111) crystal plane. Substrate 102 can be made of a semiconductor material such as, but is not limited to, silicon (Si). In some embodiments, substrate 102 can include (i) an elementary semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Alternatively, substrate 102 can be made from an electrically non-conductive material, such as a glass wafer, a sapphire wafer, and a plastic material.

In some embodiments, as shown in FIG. 2, transition layer 104 can include a nucleation layer 104A, a graded buffer layer 104B, and a super lattice layer 104C. In some embodiments, nucleation layer 104A can include an epitaxially-grown layer of aluminum nitride (AlN) on substrate 102. Nucleation layer 104A can promote the formation of subsequent AlGaN and GaN layers. In some embodiments, nucleation layer 104A can have a thickness in a range of about 5 Å to about 30 Å. In some embodiments, graded buffer layer 104B can include one or more layers of Al₁₋ₓGaₓN, where x can range from about 0 to about 1. In some embodiments, graded buffer layer 104B can include AlGaN layers having high Al concentrations formed on nucleation layer 104A and AlGaN layers having lower Al concentrations formed thereon. Graded buffer layer 104B can minimize a lattice mismatch between subsequently-grown GaN layers and substrate 102. In some embodiments, graded buffer layer 104B can have a thickness in a range of about 300 nm to about 1500 nm. In some embodiments, super lattice layer 104C can include carbon doped GaN layers for the subsequent growth of first GaN layer 106. In some embodiments, supper lattice layer 104C can have a thickness in a range of about 1 μm to about 2 μm. In some embodiments, transition layer 104 can include any number of alternating layers of AlN, AlGaN, and GaN. In some embodiments, transition layer 104 can have a same crystallographic orientation as a top surface of substrate 102. In some embodiments, transition layer 104 can have a total thickness in a range of about 3 μm to about 6 μm.

Referring to FIG. 2, first GaN layer 106 can be disposed on transition layer 104. In some embodiments, first GaN layer 106 can be an epitaxially-grown layer of GaN having a thickness from about 1 μm to about 2 μm. In some embodiments, first GaN layer 106 can be doped with n-type dopants, such as carbon and Si.

Referring to FIG. 2, AlGaN layer 108 can be disposed on first GaN layer 106. In some embodiments, AlGaN layer 108 can be grown epitaxially on first GaN layer 106. Alternatively, layer 108 can be made of AlInN. In some embodiments, AlGaN layer 108 can have a thickness between about 10 nm and about 50 nm. In some embodiments, AlGaN layer 108 can be in the form of Al₁₋ₓGaₓN and the value of x can be in the range of about 0.8 to about 0.85, or about 80% to about 85%. In some embodiments, AlGaN layer 108 can include a source region 108S, a drain region 108D, and a channel region between source region 108S and drain region 108D.

The interface between AlGaN layer 108 and first GaN layer 106, or the AlGaN/GaN heterojunction, can induce a two dimensional electron gas (2DEG) to form in an upper region of first GaN layer 106. In some embodiments, the 2DEG can be a polarization induced sheet charge formed at the interface of AlGaN and GaN layers. Both piezoelectric polarization and spontaneous polarization effects can contribute to the formation of the 2DEG. The 2DEG in GaN device 100 can have high electron mobility, for which GaN device 100 can be referred to as “GaN HEMT device.”

In some embodiments, second GaN layer 116 can include a p-type GaN (pGaN) layer acting as a gate structure of GaN device 100. The pGaN layer can be deposited and patterned to form second GaN layer 116. In some embodiments, second GaN layer 116 can have a thickness from about 50 nm to about 200 nm. In some embodiments, second GaN layer 116 can be doped with a p-type dopant, such as magnesium (Mg). In some embodiments, the doping concentration of second GaN layer 116 can range from about 1×10¹⁸ cm⁻³ to about 1×10¹⁹ cm⁻³. In some embodiments, second GaN layer 116 can have a width 116w along an X-axis ranging from about 2 μm to about 3 μm.

When a voltage is applied to second GaN layer 116, the polarization effect can cause a 2DEG to form in first GaN layer 106, directly underneath second GaN layer 116, thus causing the 2DEG to become continuous along the upper region of first GaN layer 106. When a voltage exceeding a threshold voltage of GaN device 100 is applied, the two dimensional electron gas under the gate can be enhanced sufficiently to conduct a current within first GaN layer 106. In some embodiments, the presence of AlGaN layer 108 directly underneath second GaN layer 116 permits AlGaN layer 108 to control, either partially or fully, the threshold voltage of GaN device 100. The threshold voltage, in turn, determines whether or not GaN device 100 switches on in response to a voltage applied to second GaN layer 116.

Referring to FIG. 2, isolation regions 110 can cut off the 2DEG at an AlGaN/GaN heterojunction interface and provide electrical isolation between adjacent GaN HEMT devices and/or neighboring active and passive elements (not shown) integrated with or deposited on substrate 102. Isolation regions 110 can include regions of first GaN layer 106 and AlGaN layer 108 implanted with oxygen. In some embodiments, isolation regions 110 can have a depth along a Z-axis ranging from about 100 nm to about 1500 nm.

In some embodiments, first and second S/D contact structures 114D and 114S can be ohmic contacts disposed on AlGaN layer 108. In some embodiments, first and second S/D contact structures 114D and 114S can be disposed at opposite sides of gate contact structure 120. First and second S/D contact structures 114D and 114S can connect to drain and source regions 108D and 108S of AlGaN layer 108, respectively. In some embodiments, first S/D contact structure 114D can be referred to as a “drain contact structure.” Second S/D contact structure 114S can be referred to as a “source contact structure.” In some embodiments, first and second S/D contact structures 114D and 114S can include titanium (Ti), titanium nitride (TiN), aluminum (Al), copper (Cu), nickel (Ni), molybdenum (Mo), platinum (Pt), tantalum (Ta), iridium (Ir), and other suitable conductive materials. Gate contact structure 120 can be ohmic contacts disposed on second GaN layer 116. In some embodiments, gate contact structure 120 can include Ti, TiN, Al, Cu, Pt, and other suitable conductive materials.

In some embodiments, a first distance d1 between first S/D contact structure 114D and gate contact structure 120 can be greater than a second distance d2 between second S/D contact structure 114S and gate contact structure 120. In some embodiments, the first distance d1 can range from about 15 μm to about 20 μm. The region between first S/D contact structure 114D and gate contact structure 120 can be referred to as a “drift region.” Manufacturing defects formed in the drift region may not lead to immediate device failure, but subsequent device failure in an HTRB test may occur after a certain time (e.g., about 150 hours, about 500 hours). In some embodiments, the second distance d2 can range from about 0.5 μm to about 1 μm. Manufacturing defects formed between second S/D contact structure 114S and gate contact structure 120 may lead to an electrical short between S/D and gate contact structures and thus immediate device failure, which may be easier to detect for various device tests.

In some embodiments, passivation layer 122 can be disposed on AlGaN layer 108 and second GaN layer 116 to passivate top surfaces of AlGaN layer 108 and second GaN layer 116. In some embodiments, passivation layer 122 can include oxide, nitride, or oxynitride. In some embodiments, passivation layer 122 can include aluminum oxide. In some embodiments, passivation layer 122 can have a thickness in the range of about 150 nm to about 250 nm.

In some embodiments, nitride layer 124 can be disposed on passivation layer 122 and can provide electrical isolation among gate contact structure 120, first S/D contact structure 114D, and second S/D contact structure 114S. In some embodiments, nitride layer 124 can include silicon nitride or other suitable dielectric materials. In some embodiments, nitride layer 124 can have a thickness ranging from about 60 nm to about 100 nm.

In some embodiments, oxide layer 126 can be disposed on nitride layer 124 and can provide electrical isolation between first field plate 130 and metal vias 136. In some embodiments, oxide layer 126 can include silicon oxide or other suitable dielectric materials. In some embodiments, oxide layer 126 can have a thickness ranging from about 150 nm to about 250 nm.

In some embodiments, ILD layer 128 can be disposed on oxide layer 126 and can provide electrical isolation between second field plate 134 and metal vias 136. In some embodiments, ILD layer 128 can include silicon oxide or other suitable dielectric materials. In some embodiments, ILD layer 128 can have a thickness ranging from about 1000 nm to about 2000 nm.

Referring to FIGS. 1 and 2, in some embodiments, first field plate 130 and one or more artificial field plates 132 can be disposed on nitride layer 124. In some embodiments, first field plate 130 and artificial field plates 132 can be formed in a same process and can include Ti, TiN, or other suitable conductive materials. In some embodiments, first field plate 130 can have a width 130w along an X-axis ranging from about 2 μm to about 3 μm. In some embodiments, first field plate 130 can be disposed adjacent to gate contact structure 120 and between gate contact structure 120 and first S/D contact structure 114D. In some embodiments, a distance 130d between the first field plate 130 and first S/D contact structure 114D can range from about 12 μm to about 18 μm. In some embodiments, a ratio of distance 130d to distance d1 of the drift region can range from about 75% to about 85%. In some embodiments, first field plate 130 can be electrically connected to second S/D contact structure 114S to reduce nonhomogeneous electric field distribution around gate contact structure 120.

In some embodiments, artificial field plates 132 can be uniformly disposed between first S/D contact structure 114D and gate contact structure 120 to monitor manufacturing defects formed in the drift region and improve electric field uniformity and thus device performance. In some embodiments, artificial field plates 132 can be between second S/D contact structure 114S and gate contact structure 120. In some embodiments, artificial field plates 132 can improve defect detection sensitivity during device tests and can help evaluate device performance impact of defects in the drift region above AlGaN layer 108. In some embodiments, artificial field plates 132 can improve electric field uniformity between gate contact structure 120 and first S/D contact structure 114D and thus improve device performance.

In some embodiments, artificial field plates 132 can have a pattern size ranging from about 0.5 μm² to about 10 μm². If the pattern size is less than about 0.5 μm², the defect detection sensitivity may decrease and the device performance may degrade. If the pattern size is greater than about 10 μm², artificial field plates 132 may short to adjacent structures.

In some embodiments, a distance between artificial field plates 132 and first S/D contact structure 114D can range from about 1 μm to about 18 μm. If the distance is less than about 1 μm, artificial field plates 132 may short to first S/D contact structure 114D. If the distance is greater than about 18 μm, artificial field plates 132 may short to gate contact structure 120.

In some embodiments, a number of artificial field plates 132 can range from about 1 to about 1000. If the number is less than about 1, artificial field plates 132 may not improve the defect detection sensibility and the electric field uniformity. If the number is greater than about 1000, artificial field plates 132 may short to adjacent structures and manufacturing cost may increase.

In some embodiments, artificial field plates 132 can include p-type GaN in second GaN layer 116 formed in a same process. In some embodiments, artificial field plates 132 can include conductive materials in first and second S/D contact structures 114D and 114S or second field plate 134 formed in a same process. In some embodiments, artificial field plates 132 can include conductive materials in metal lines 138B formed in a same process, such as Al and Cu.

Referring to FIGS. 1 and 2, in some embodiments, second field plate 134 can be disposed on first field plate 130. In some embodiments, second field plate 134 can include TiN or other conductive materials. In some embodiments, a distance 134d between the second field plate 134 and first S/D contact structure 114D can range from about 8 μm to about 15 μm. Third field plate 138A can be disposed on second field plate 134. In some embodiments, third field plate 138A can include Al, Cu, or other conductive materials. In some embodiments, a distance 138d between third field plate 138A and first S/D contact structure 114D can range from about 6 μm to about 10 μm. In some embodiments, first, second, and third field plates 130, 134, and 138A can be connected to second S/D contact structure 114S through metal vias 136 and can be electrically biased at ground. In some embodiments, first field plate 130 can be referred to as a “gate field plate (GFP)” because first field plate 130 can be formed in a same process as gate contact structure 120. In some embodiments, second field plate 134 can be referred as a “TiN field plate (TFP)” because second field plate 134 can include TiN. In some embodiments, third field plate 138A can be referred as a “source field plate (SFP)” because third field plate 138A can be connected to second S/D contact structure 114S. In some embodiments, metal vias 136 can include tungsten (W) or other suitable conductive materials. In some embodiments, metal lines 138B can be disposed on ILD layer 128 and formed in a same process as third field plate 138A. In some embodiments, metal lines 138B can include Al, Cu, or other suitable conductive materials. In some embodiments, metal lines 138B can be a portion of an interconnect structure (not shown) of GaN device 100.

FIG. 3 illustrates a schematic diagram showing a GaN device 100 in the context of a circuit, in accordance with some embodiments of the present disclosure. Circuit 150 can include GaN device 100 electrically connected to a driver stage 152 configured to apply a voltage to a gate terminal of GaN device 100 (e.g., gate contact structure 120 or second GaN layer 116). In response to the applied voltage reaching a threshold voltage, a source voltage Vss (e.g., ground) at the source terminal (e.g., second S/D contact structure 114S or source region 108S) can appear at the drain terminal (e.g., first S/D contact structure 114D or drain region 108D) of GaN device 100 as an output voltage Vout, to which a load can be connected.

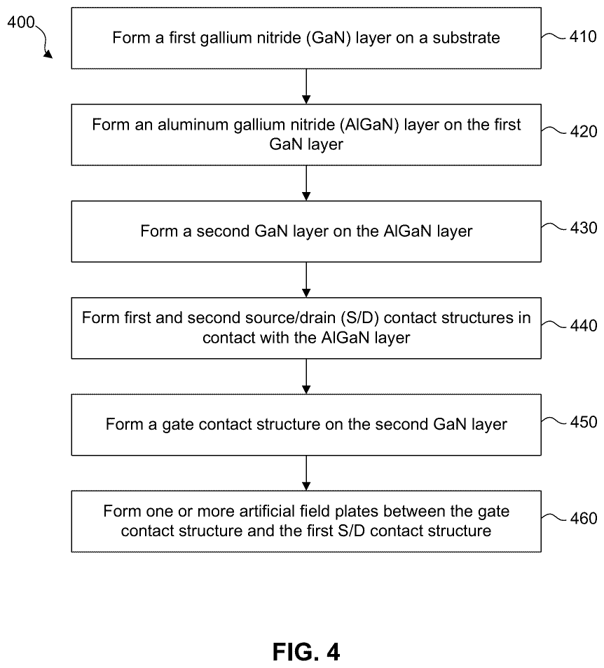

FIG. 4 is a flow diagram of a method 400 for fabricating GaN device 100 having artificial field plates, in accordance with some embodiments of the present disclosure. Method 400 may not be limited to GaN device 100 and can be applicable to other devices that would benefit from the artificial field plates. Additional fabrication operations may be performed between various operations of method 400 and may be omitted merely for clarity and ease of description. Additional processes can be provided before, during, and/or after method 400; one or more of these additional processes are briefly described herein. Moreover, not all operations may be needed to perform the disclosure provided herein. Additionally, some of the operations may be performed simultaneously or in a different order than shown in FIG. 4. In some embodiments, one or more other operations may be performed in addition to or in place of the presently described operations.

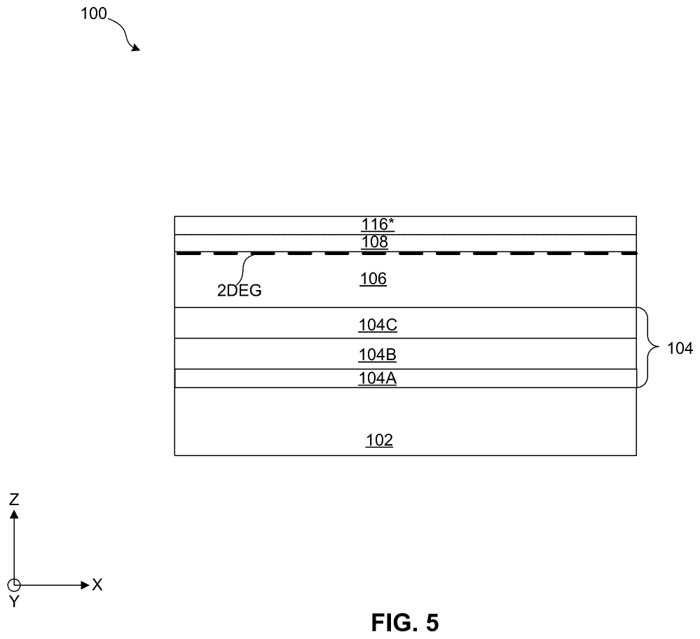

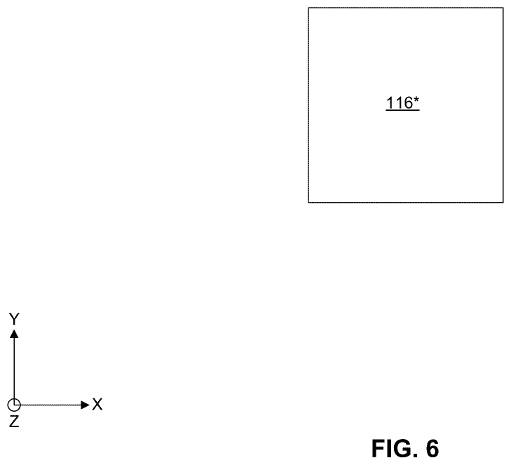

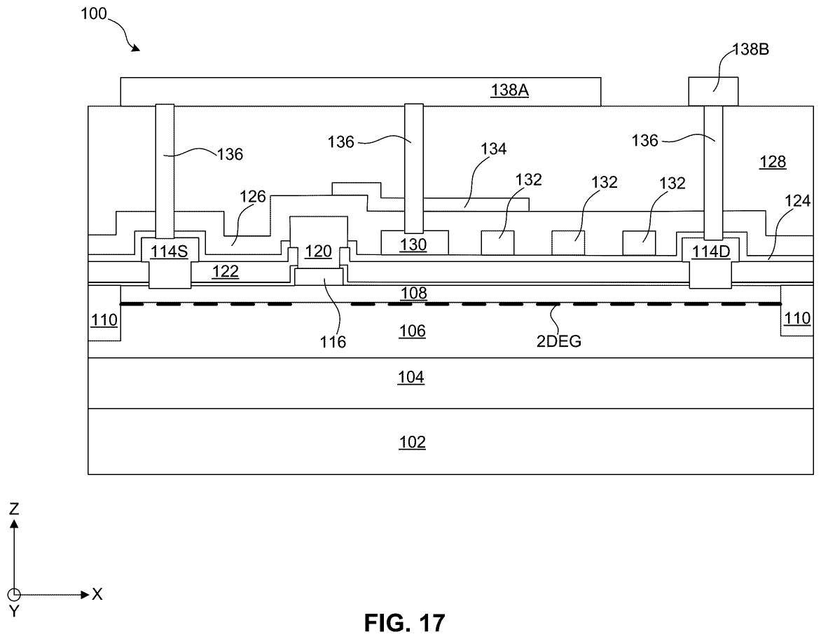

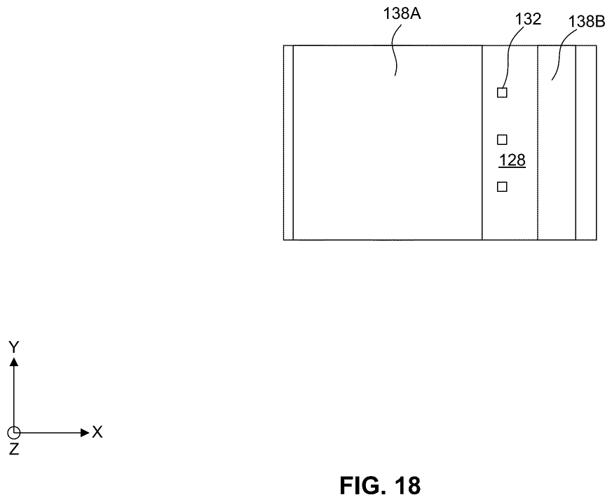

For illustrative purposes, the operations illustrated in FIG. 4 will be described with reference to the example fabrication process for fabricating GaN device 100 as illustrated in FIGS. 5-18. FIGS. 5, 7, 9, 11, 13, 15, and 17 illustrate cross-sectional views of GaN device 100 having artificial field plates at various stages of its fabrication, in accordance with some embodiments. FIGS. 6, 8, 10, 12, 14, 16, and 18 illustrate plan views of GaN device 100 having artificial field plates at various stages of its fabrication, in accordance with some embodiments. Elements in FIGS. 5-18 with the same annotations as elements in FIGS. 1-3 are described above.

In referring to FIG. 4, method 400 begins with operation 410 and the process of forming a first GaN layer on a substrate. For example, as shown in FIG. 5, first GaN layer 106 can be formed on substrate 102. In some embodiments, substrate 102 can include a crystalline semiconductor layer with its top surface parallel to the (111) crystal plane. Substrate 102 can be made of a semiconductor material such as Si. In some embodiments, transition layer 104 can be blanket deposited on substrate 102 to minimize lattice mismatch and promote subsequent growth of GaN layers. First GaN layer 106 can be blanket deposited on transition layer 104. In some embodiments, transition layer 104 and first GaN layer 106 can be blanket deposited by metal oxide chemical vapor deposition (MOCVD) or other suitable deposition methods. In some embodiments, transition layer 104 and first GaN layer 106 can be epitaxially grown on substrate 102. In some embodiments, transition layer 104 can include nucleation layer 104A, graded buffer layer 104B, and super lattice layer 104C to gradually increase the gallium concentration and thus lattice constant for the growth of first GaN layer 106.

Referring to FIG. 4, in operation 420, an AlGaN layer is formed on the first GaN layer. For example, as shown in FIG. 5, AlGaN layer 108 can be formed on first GaN layer 106. In some embodiments, AlGaN layer 108 can be blanket deposited on first GaN layer 106 by MOCVD or other suitable deposition methods. In some embodiments, AlGaN layer 108 can be epitaxially grown on first GaN layer 106. In some embodiments, AlGaN layer 108 can be in the form of Al₁₋ₓGaₓN and the value of x can be in the range of about 0.8 to about 0.85, or about 80% to about 85%. The interface between AlGaN layer 108 and first GaN layer 106, or the AlGaN/GaN heterojunction, can introduce a 2DEG in an upper region of first GaN layer 106 by piezoelectric polarization and spontaneous polarization effects.

Referring to FIG. 4, in operation 430, a second GaN layer is formed on the AlGaN layer. For example, as shown in FIGS. 5 and 6, second GaN layer 116* can be formed on AlGaN layer 108. In some embodiments, second GaN layer 116* can be blanket deposited on AlGaN layer 108 by chemical vapor deposition (CVD), MOCVD, low pressure chemical vapor deposition (LPCVD), plasma enhanced chemical vapor deposition (PECVD), high density plasma CVD (HDPCVD), atomic layer deposition (ALD), ultrahigh vacuum CVD (UHVCVD), reduced pressure CVD (RPCVD), or other suitable deposition methods. In some embodiments, second GaN layer 116* can be epitaxially grown on AlGaN layer 108. In some embodiments, second GaN layer 116* can have a dopant type different from a dopant type of first GaN layer 106. For example, first GaN layer 106 can include n-type dopants, such as carbon and Si. Second GaN layer 116* can include p-type dopants, such as Mg. In some embodiments, the doping concentration of second GaN layer 116 can range from about 1×10¹⁸ cm⁻³ to about 1×10¹⁹ cm⁻³.

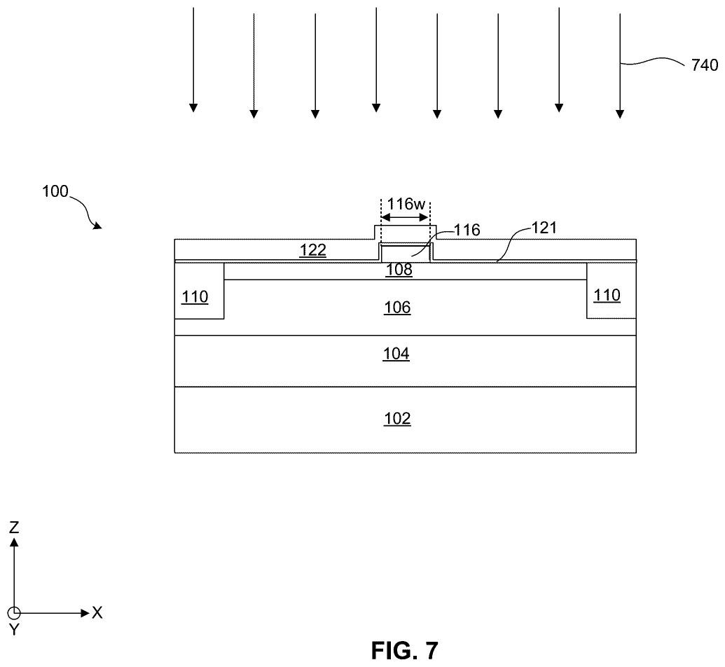

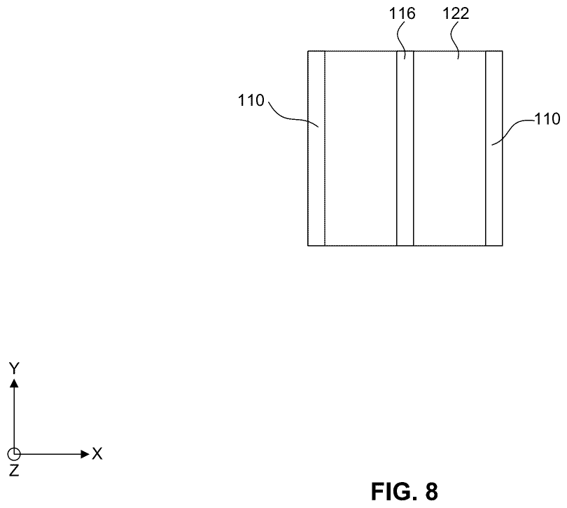

In some embodiments, blanket deposited second GaN layer 116* can be patterned and etched to form second GaN layer 116, as shown in FIGS. 7 and 8. In some embodiments, second GaN layer 116 can have width 116w along an X-axis ranging from about 2 μm to about 3 μm. The formation of second GaN layer 116 can be followed by the formation of passivation layer 122, as shown in FIGS. 7 and 8. In some embodiments, as shown in FIG. 7, an interfacial layer 121 can be formed on AlGaN layer 108 and second GaN layer 116 to promote the formation of passivation layer 122. In some embodiments, passivation layer 122 can be blanket deposited on AlGaN layer 108 and second GaN layer 116 by CVD, ALD, PECVD, spin coating, or other suitable deposition methods. In some embodiments, passivation layer 122 can include oxide, nitride, or oxynitride to passivate top surfaces of AlGaN layer 108 and second GaN layer 116. In some embodiments, passivation layer 122 can include aluminum oxide. The formation of passivation layer 122 can be followed by an implant process 740 to form isolation regions 110, as shown in FIGS. 7 and 8. In some embodiments, implant process 740 can implant oxygen into AlGaN layer 108 and first GaN layer 106. In some embodiments, a patterning process can define isolation regions 110 for implant process 740 and a mask layer (not shown) can be formed on passivation layer 122 to protect regions outside isolation regions 110. In some embodiments, isolation regions 110 can have a depth along a Z-axis ranging from about 100 nm to about 1500 nm.

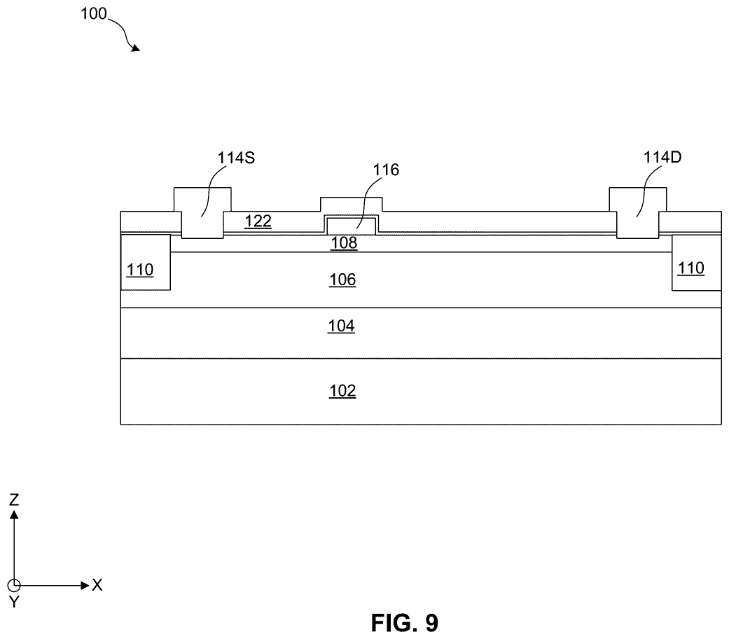

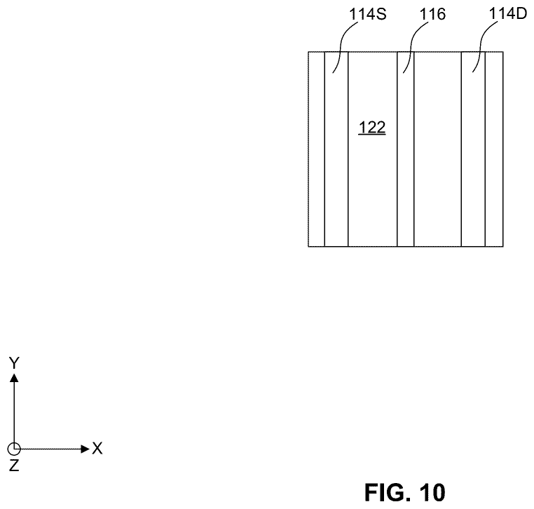

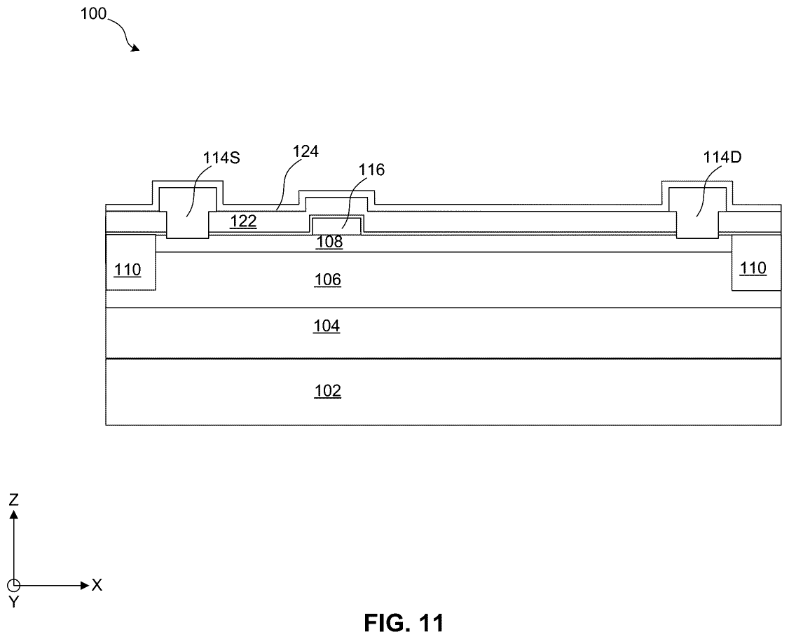

Referring to FIG. 4, in operation 440, first and second S/D contact structures are formed in contact with the AlGaN layer. For example, as shown in FIGS. 9 and 10, first and second S/D contact structures 114D and 114S can be formed in contact with AlGaN layer 108. In some embodiments, a patterning process can define locations of first and second S/D contact structures 114D and 114S using a photoresist mask, a hard mask, or combinations thereof. An etching process can form openings in passivation layer 122 and/or AlGaN layer 108 to expose AlGaN layer 108. Conductive materials can be deposited in the openings to form ohmic contacts between AlGaN layer 108 and first and second S/D contact structures 114D and 114S. In some embodiments, first and second S/D contact structures 114D and 114S can have a T-shape as shown in FIGS. 2 and 11. In some embodiments, first and second S/D contact structures 114D and 114S can include a metal or a metal alloy formed by a plating process, such as electroplating and electro-less plating. In some embodiments, first and second S/D contact structures 114D and 114S can include a multilayer metal stack formed by a multi-step deposition process. In some embodiments, first and second S/D contact structures 114D and 114S can include metals, for example, Ti, TiN, Al, Cu, Ni, Mo, Pt, Ta, Ir, or combinations thereof.

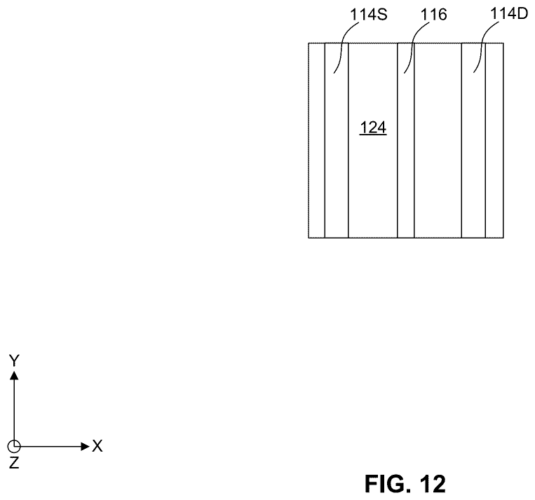

In some embodiments, the formation of first and second S/D contact structures 114D and 114S can be followed by the formation of nitride layer 124, as shown in FIGS. 11 and 12. In some embodiments, nitride layer 124 can be blanket deposited on passivation layer 122 and first and second S/D contact structures 114D and 114S by CVD, ALD, or other suitable deposition methods. In some embodiments, nitride layer 124 can include silicon nitride or other suitable dielectric materials. In some embodiments, nitride layer 124 can have a thickness ranging from about 60 nm to about 100 nm.

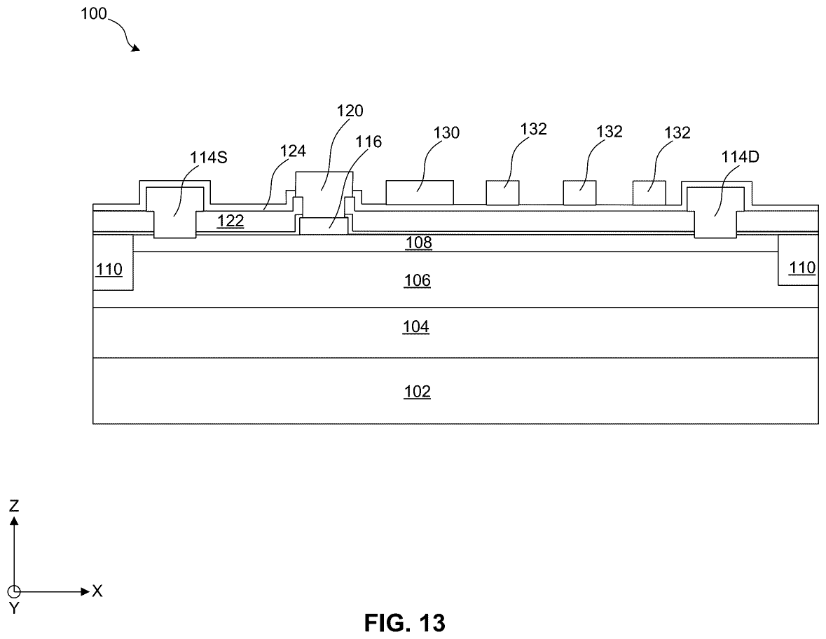

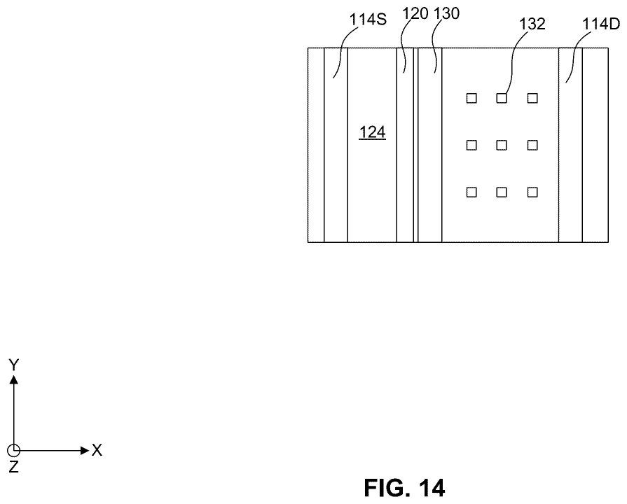

Referring to FIG. 4, in operation 450, a gate contact structure is formed on the second GaN layer. For example, as shown in FIGS. 13 and 14, gate contact structure 120 can be formed on second GaN layer 116. In some embodiments, a patterning process can define gate contact structure 120 using a photoresist mask, a hard mask, or combinations thereof. An etching process can form an opening in nitride layer 124 and passivation layer 122 to expose second GaN layer 116. Conductive materials can be deposited in the opening and in contact with second GaN layer 116 to form gate contact structure 120.

Referring to FIG. 4, in operation 460, one or more artificial field plates are formed between the gate contact structure and the first S/D contact structure. For example, as shown in FIGS. 13 and 14, first field plate 130 and artificial field plates 132 can be formed between gate contact structure 120 and first S/D contact structure 114D. In some embodiments, first field plate 130 and artificial field plates 132 can be defined in the same patterning process as gate contact structure 120. After deposition of the conductive materials and removal of the photoresist mask and hard mask, gate contact structure 120 can be formed in contact with second GaN layer 116. First field plate 130 and artificial field plates 132 can be formed on nitride layer 124 between gate contact structure 120 and first S/D contact structure 114D. In some embodiments, artificial field plates 132 can be formed between gate contact structure 120 and second S/D contact structure 114S (not shown). In some embodiments, gate contact structure 120, first field plate 130, and artificial field plates 132 can include Ti, TiN, Al, Cu, Ni, Mo, Pt, Ta, Ir, or other suitable conductive materials.

In some embodiments, artificial field plates 132 can be uniformly disposed between first S/D contact structure 114D and gate contact structure 120 to monitor manufacturing defects formed in the drift region and improve electric field uniformity and thus device performance. In some embodiments, artificial field plates 132 can improve defect detection sensitivity during device tests and can help evaluate device performance impact of defects above AlGaN layer 108 in the drift region. In some embodiments, artificial field plates 132 can improve electric field uniformity between gate contact structure 120 and first S/D contact structure 114D and thus improve device performance.

In some embodiments, artificial field plates 132 can have a pattern size ranging from about 0.5 μm² to about 10 μm². If the pattern size is less than about 0.5 μm², the defect detection sensitivity may decrease and the device performance may degrade. If the pattern size is greater than about 10 μm², artificial field plates 132 may short to adjacent structures.

In some embodiments, a distance between artificial field plates 132 and first S/D contact structure 114D can range from about 1 μm to about 18 μm. If the distance is less than about 1 μm, artificial field plates 132 may short to first S/D contact structure 114D. If the distance is greater than about 18 μm, artificial field plates 132 may short to gate contact structure 120.

In some embodiments, a number of artificial field plates 132 can range from about 1 to about 1000. If the number is less than about 1, artificial field plates 132 may not improve the defect detection sensibility and the electric field uniformity. If the number is greater than about 1000, artificial field plates 132 may short to adjacent structures and manufacturing cost may increase.

In some embodiments, artificial field plates 132 can be formed during the operation of forming second GaN layer 116 and artificial field plates 132 can include p-type GaN. In some embodiments, artificial field plates 132 can be formed during the operation of forming first and second S/D contact structures 114D and 114S and artificial field plates 132 include conductive materials the same as first and second S/D contact structures 114D and 114S. In some embodiments, artificial field plates 132 can be formed during the operation of forming second field plate 134 and artificial field plates 132 include conductive materials the same as second field plate 134. In some embodiments, artificial field plates 132 can be formed during the operation of forming metal lines 138B and artificial field plates 132 include conductive materials the same as metal lines 138B.

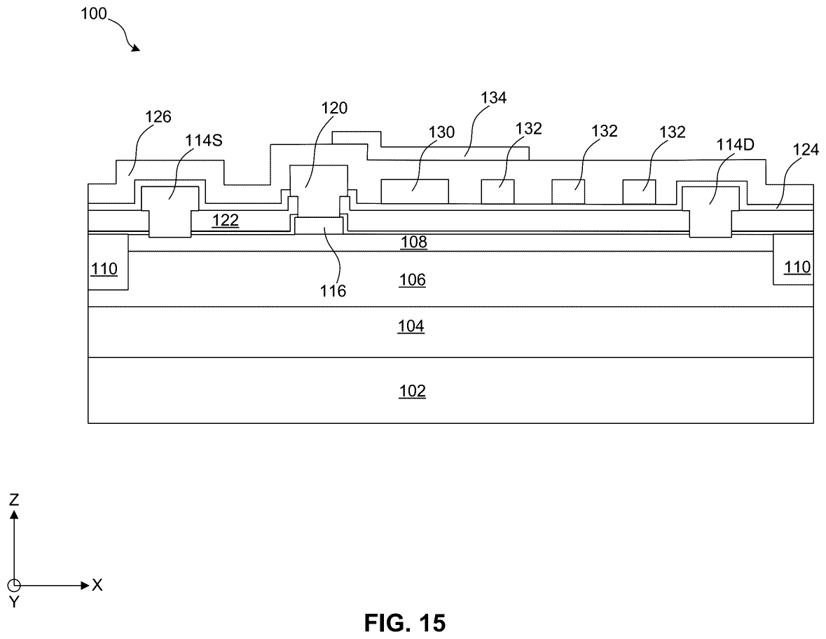

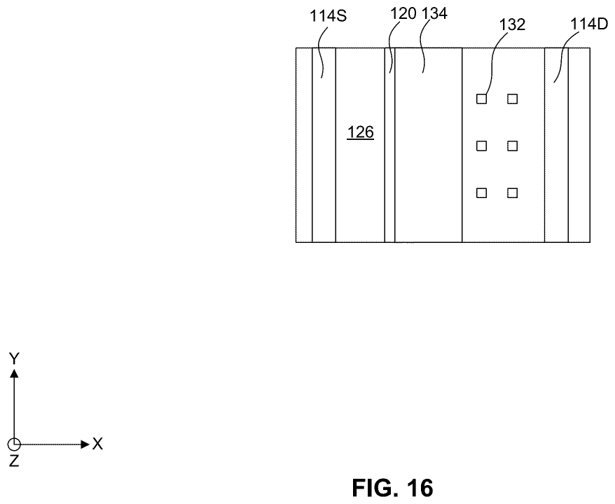

The formation of artificial field plates 132 can be followed by the formation of oxide layer 126, as shown in FIGS. 15 and 16. In some embodiments, oxide layer 126 can be blanket deposited on nitride layer 124, gate contact structure 120, first field plate 130, and artificial field plates 132 by CVD, ALD, or other suitable deposition methods. In some embodiments, oxide layer 126 can include silicon oxide or other suitable dielectric materials.

The formation of oxide layer 126 can be followed by the formation of second field plate 134, as shown in FIGS. 15 and 16. In some embodiments, conductive materials can be blanket deposited on oxide layer 126 by MOCVD or other suitable deposition methods. A patterning process can define second field plate 134 using a photoresist mask, a hard mask, or combinations thereof. An etching process can remove the deposited conductive materials outside second field plate 134.

The formation of second field plate 134 can be followed by the blanket deposition of ILD layer 128, the formation of metal vias 136, and the formation of third field plate 138A and metal lines 138B, the detailed processes of which are omitted merely for clarity and ease of description. In some embodiments, first, second, and third field plates 130, 134, and 138A can be electrically connected to second S/D contact structure 114S through metal vias 136. In some embodiments, artificial field plates 132 can be physically and electrically separated from first and second S/D contact structures 114D and 114S.

Various embodiments in the present disclosure provide example methods for forming artificial field plates 132 in GaN device 100. GaN device 100 can include first GaN layer 106 on substrate 102, AlGaN layer 108 on first GaN layer 106, and second GaN layer 116 on AlGaN layer 108. First and second S/D contact structures 114D and 114S can be in contact with AlGaN layer 108. Gate contact structure 120 can be in contact with second GaN layer 116. One or more artificial field plates 132 can be located between gate contact structure 120 and first S/D contact structure 114D, and can be physically and electrically separated from first and second S/D structures 114D and 114S. In some embodiments, artificial field plates 132 can increase defect detection sensitivity of GaN device 100 during tests and can help evaluate device performance impact of defects in the drift region. In some embodiments, artificial field plates 132 can improve electric-field uniformity between gate contact structure 120 and first S/D contact structure 114D and improve device performance. In some embodiments, artificial field plates 132 can reduce manufacturing cost and improve defect control of GaN device 100.

In some embodiments, a semiconductor device includes a gate structure and first and second source/drain (S/D) regions on a substrate, a gate contact structure electrically connected to the gate structure, first and second S/D contact structures electrically connected to the respective first and second S/D regions, and one or more artificial field plates disposed between the gate contact structure and the first S/D contact structure. The one or more artificial field plates are electrically separated from the first and second S/D contact structures.

In some embodiments, a semiconductor device includes a first gallium nitride (GaN) layer on a substrate, an aluminum gallium nitride (AlGaN) layer on the first GaN layer, a second GaN layer on the AlGaN layer, a gate contact structure in contact with the second GaN layer, first and second source/drain (S/D) contact structures in contact with the AlGaN layer, and one or more artificial field plates disposed above the AlGaN layer and between the gate contact structure and the first S/D contact structure. The first and second S/D contact structures are disposed at opposite sides of the gate contact structure. The one or more artificial field plates are separated from the first and second S/D contact structures.

In some embodiments, a method includes forming a first gallium nitride (GaN) layer on a substrate, forming an aluminum gallium nitride (AlGaN) layer on the first GaN layer, forming a second GaN layer on the AlGaN layer, forming first and second source/drain (S/D) contact structures in contact with the AlGaN layer, forming a gate contact structure in contact with the second GaN layer, and forming one or more artificial field plates between the gate contact structure and the first S/D contact structure. The first and second S/D contact structures are disposed at opposite sides of the second GaN layer. The one or more artificial field plates are separated from the first and second S/D contact structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a gate structure and first and second source/drain (S/D) regions on a substrate;
a gate contact structure electrically connected to the gate structure;
first and second S/D contact structures electrically connected to the first and second S/D regions, respectively; and
one or more artificial field plates disposed between the gate contact structure and the first S/D contact structure, wherein the one or more artificial field plates are electrically separated from the first and second S/D contact structures.

2. The semiconductor device of claim 1, wherein the first S/D region is a drain region and the first S/D contact structure is electrically connected to the drain region.

3. The semiconductor device of claim 1, wherein a first distance between the first S/D contact structure and the gate contact structure is greater than a second distance between the second S/D contact structure and the gate contact structure.

4. The semiconductor device of claim 1, wherein a distance between the first S/D contact structure and the one or more artificial field plates ranges from about 1 μm to about 18 μm.

5. The semiconductor device of claim 1, wherein a size of each of the one or more artificial field plates ranges from about 0.5 μm² to about 10 μm².

6. The semiconductor device of claim 1, wherein a number of the one or more artificial field plates ranges from about 1 to about 1000.

7. The semiconductor device of claim 1, further comprising an additional field plate disposed between the gate contact structure and the first S/D contact structure and electrically connected to the second S/D contact structure, wherein the one or more artificial field plates are disposed between the additional field plate and the first S/D contact structure.

8. The semiconductor device of claim 1, wherein the one or more artificial field plates comprise a conductive material in the gate structure, a conductive material in the gate contact structure, a conductive material in the first and second S/D contact structures, or a conductive material in an interconnect structure of the semiconductor device.

9. A semiconductor device, comprising:
a first gallium nitride (GaN) layer on a substrate;
an aluminum gallium nitride (AlGaN) layer on the first GaN layer;
a second GaN layer on the AlGaN layer;
a gate contact structure in contact with the second GaN layer;
first and second source/drain (S/D) contact structures in contact with the AlGaN layer, wherein the first and second S/D contact structures are disposed at opposite sides of the gate contact structure; and
one or more artificial field plates disposed above the AlGaN layer and between the gate contact structure and the first S/D contact structure, wherein the one or more artificial field plates are separated from the first and second S/D contact structures.

10. The semiconductor device of claim 10, wherein the first S/D contact structure is a drain contact structure and the first and second GaN layers comprise different types of dopants.

11. The semiconductor device of claim 10, wherein a first distance between the first S/D contact structure and the gate contact structure is greater than a second distance between the second S/D contact structure and the gate contact structure.

12. The semiconductor device of claim 10, wherein a distance between the first S/D contact structure and the one or more artificial field plates ranges from about 1 μm to about 18 μm.

13. The semiconductor device of claim 10, wherein a size of each of the one or more artificial field plates ranges from about 0.5 μm² to about 10 μm².

14. The semiconductor device of claim 10, wherein a number of the one or more artificial field plates ranges from about 1 to about 1000.

15. The semiconductor device of claim 10, further comprising an additional field plate disposed between the gate contact structure and the first S/D contact structure and electrically connected to the first S/D contact structure, wherein the one or more artificial field plates are disposed between the additional field plate and the first S/D contact structure.

16. The semiconductor device of claim 10, wherein the one or more artificial field plates comprise GaN, titanium nitride, titanium, or copper.

17. A method, comprising:
forming a first gallium nitride (GaN) layer on a substrate;
forming an aluminum gallium nitride (AlGaN) layer on the first GaN layer;
forming a second GaN layer on the AlGaN layer;
forming first and second source/drain (S/D) contact structures in contact with the AlGaN layer, wherein the first and second S/D contact structures are disposed at opposite sides of the second GaN layer;
forming a gate contact structure in contact with the second GaN layer; and
forming one or more artificial field plates between the gate contact structure and the first S/D contact structure, wherein the one or more artificial field plates are separated from the first and second S/D contact structures.

18. The method of claim 17, wherein forming the first and second S/D contact structures comprises:
forming the first S/D contact structure having a first distance from the gate contact structure; and
forming the second S/D contact structure having a second distance from the gate contact structure, wherein the first distance is greater than the second distance.

19. The method of claim 17, wherein forming the one or more artificial field plates comprises forming the one or more artificial field plates at a distance ranging from about 1 μm to about 18 μm from the first S/D contact structure.

20. The method of claim 17, wherein forming the one or more artificial field plates comprises forming the one or more artificial field plates having a size ranging from about 0.5 μm² to about 10 μm².
